(19) United States
(12) Patent Application Publication
(10) Pub. No.: US 2023/0256550 A1
(43) Pub. Date: Aug. 17, 2023

(54) AUXILIARY SHEET, AUXILIARY SHEET MANUFACTURING METHOD, AND SUCTION-ATTACHMENT METHOD

(71) Applicant: FANUC CORPORATION, Yamanashi (JP)

(72) Inventor: Masahiro MUROTA, Yamanashi-ken (JP)

(21) Appl. No.: 18/018,067

(22) PCT Filed: Jul. 27, 2021
(86) PCT No.: PCT/JP2021/027624

§ 371 Date: Jan. 26, 2023

(30) Foreign Application Priority Data
Jul. 30, 2020 (JP) 2020-128795

(51) Int. Cl. B23Q 3/10; B23Q 3/08; B30B 15/06

(52) U.S. Cl. CPC B23Q 3/105; B23Q 3/088; B30B 15/064; B23Q 2703/04

(57) ABSTRACT

An auxiliary sheet, an auxiliary sheet manufacturing method, and a suction-attachment method with which it is possible to stabilize the attachment of an object being attached by suction. An auxiliary sheet according to an embodiment is provided with: a plurality of first regions having elasticity and including a plurality of pores arranged continuously to allow for passage of air; and one or a plurality of second regions having elasticity and in which the amount of passage of air is less than in the plurality of first regions. The plurality of first regions and the one or a plurality of second regions are disposed alternately, with those of the first regions and the second regions that are adjacent to each other being in contact with each other.

### TECHNICAL FIELD

The present invention relates to an auxiliary sheet for assisting suction of a suction object, an auxiliary sheet manufacturing method, and a suction method (suction-attachment method).

### BACKGROUND ART

JP 2009-117552 A discloses a suction stage for sucking a suction object by sucking air through a flat plate. The flat plate has a plurality of holes connecting the front surface and the back surface. A sheet member is disposed on the other surface of the flat plate. Pores having air permeability in the same direction as the holes of the flat plate are formed in the sheet member. The pores has a smaller diameter than the holes of the plate. JP 2009-117552 A indicates that, by disposing the sheet member, the suction object is sucked with sufficient flatness while ensuring the rigidity of the entire suction stage.

### SUMMARY OF THE INVENTION

Incidentally, the sheet member disclosed in JP 2009-117552 A is a nonwoven fabric. The nonwoven fabric has elasticity. Therefore, when the suction object is being sucked onto the other surface of the flat plate via the sheet member, the sheet member is pressed against the flat plate. Thus, theoretically, outside air does not flow into the flat plate via the side of the sheet member.

However, at least unevenness is present on a sucking surface (the other surface of the flat plate) onto which the suction object is sucked, or a sucked surface (the surface of the suction object) which is sucked onto the sucking surface. Pressing of the sheet member against the flat plate may be limited due to the presence of this unevenness. In this case, outside air flows into the flat plate via the side of the sheet member. As a result, there is a tendency that the suction force decreases and suction of the suction object becomes unstable.

It is therefore an object of the present invention to provide an auxiliary sheet, an auxiliary sheet manufacturing method, and a suction method, which are capable of stabilizing suction of the suction object.

According to a first aspect of the present invention, there is provided an auxiliary sheet that is disposed between a suction object and a sucking surface onto which the suction object is sucked, the auxiliary sheet being configured to assist suction of the suction object, the auxiliary sheet comprising: a plurality of first regions having elasticity and each including a plurality of pores provided continuously to allow air to pass therethrough; and one or a plurality of second regions having elasticity and allowing less air to pass therethrough than the plurality of first regions, wherein the plurality of first regions and the one or plurality of second regions are alternately arranged, and the first region and the second region adjacent to each other are in contact with each other.

According to a second aspect of the present invention, there is provided a manufacturing method for manufacturing an auxiliary sheet that is disposed between a suction object and a sucking surface configured to suck the suction object, the auxiliary sheet being configured to assist suction of the suction object, the manufacturing method comprising: a pre-process of preparing a sheet that includes a first region having elasticity and including a plurality of pores arranged continuously to allow air to pass therethrough; and a forming process of forming one or a plurality of second regions in the first region, the second regions having elasticity and allowing less air to pass therethrough than a plurality of the first regions, wherein in the forming process, the one or plurality of second regions are formed in a manner so that the plurality of first regions and the one or plurality of second regions are alternately arranged, and that the first region and the second region adjacent to each other are in contact with each other.

According to a third aspect of the present invention, there is provided a suction method for causing a suction object to be sucked onto a sucking surface configured to suck the suction object, by using an auxiliary sheet that is disposed between the suction object and the sucking surface and that is configured to assist suction of the suction object, the suction method comprising: a disposing step of disposing the auxiliary sheet between a sucked surface of the suction object and the sucking surface of a table; and a suction step of causing the suction object to be sucked onto the sucking surface via the auxiliary sheet, wherein the auxiliary sheet includes a plurality of first regions having elasticity and each including a plurality of pores provided continuously to allow air to pass therethrough, and one or a plurality of second regions having elasticity and allowing less air to pass therethrough than the plurality of first regions, the plurality of first regions and the one or plurality of second regions are alternately arranged, and the first region and the second region adjacent to each other are in contact with each other.

According to the aspects of the present invention, suction of the suction object can be stabilized.

In other words, both the first region and the second region of the auxiliary sheet have elasticity. As a result, at the time of suction in which the suction object is sucked onto the sucking surface via the auxiliary sheet, the adhesion between the sucked surface of the suction object and the auxiliary sheet can be enhanced even if the sucked surface is uneven, and the adhesion between the sucking surface and the auxiliary sheet can be enhanced even if the sucking surface is uneven.

In addition, the first regions having air permeability and the second regions having air permeability lower than that of the first region are alternately arranged adjacent to each other. With this configuration, even if the pressing of the auxiliary sheet against the sucking surface is limited during suction due to the presence of unevenness in at least one of the sucked surface or the sucking surface, the second regions act to block the inflow of outside air from the side of the auxiliary sheet, whereby it is possible to suppress a decrease in suction force.

In this manner, the suction of the suction object can be stabilized.

### BRIEF DESCRIPTION OF DRAWINGS

FIG. 1 is a front view showing an auxiliary sheet according to a first embodiment;

FIG. 2 is a front view showing an auxiliary sheet according to a first modification;

FIG. 3 is a front view showing an auxiliary sheet according to a second modification;

FIG. 4 is a front view showing an auxiliary sheet according to a second embodiment;

FIG. 5 is a front view showing an auxiliary sheet according to a third embodiment;

FIG. 6 is a flow chart showing a manufacturing process of the auxiliary sheet;

FIG. 7 is a diagram showing a state in which second regions are formed;

FIG. 8 is a flowchart showing a suction process;

FIG. 9 is a diagram showing a state in which the auxiliary sheet is disposed;

FIG. 10 is a diagram showing a state at the time of suction in which a suction object is sucked onto a table via the auxiliary sheet; and

FIG. 11 is a diagram showing a state at the time of suction in which the suction object is sucked onto the table via a conventional porous sheet.

### DETAILED DESCRIPTION OF THE INVENTION

A preferred embodiment of the present invention will be described in detail below with reference to the accompanying drawings.

### Embodiment

### First Embodiment

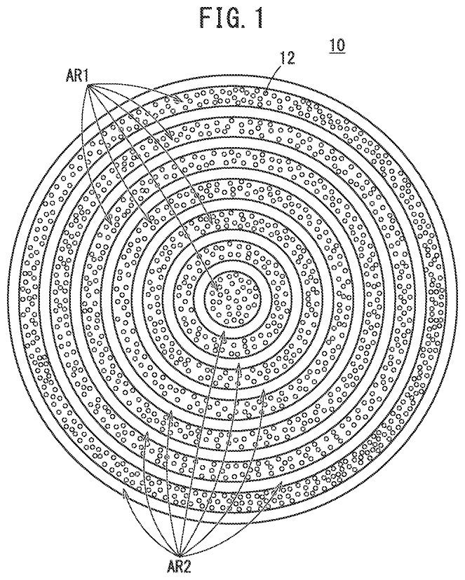

FIG. 1 is a front view showing an auxiliary sheet 10 according to a first embodiment. The auxiliary sheet 10 is disposed between the sucking surface of a suction stage and the sucked surface of a suction object. The auxiliary sheet 10 has elasticity as a whole. The auxiliary sheet 10 is formed in a circular shape. The strength of the auxiliary sheet 10 is less than that of the suction stage. The rigidity of the auxiliary sheet 10 is less than that of the suction stage. Examples of the material of the auxiliary sheet 10 include rubber and elastomer. The auxiliary sheet 10 includes a plurality of first regions AR1 and a plurality of second regions AR2.

Each of the plurality of first regions AR1 is a region having a plurality of pores 12. The pores 12 are provided continuously so that air can pass therethrough. That is, each of the plurality of first regions AR1 is an air permeable region having air permeability.

Each of the plurality of first regions AR1 has elasticity. The plurality of first regions AR1 may have the same elastic modulus. The plurality of first regions AR1 may have elastic moduli different from each other. In addition, the elastic modulus of some of the plurality of first regions AR1 may be different from the elastic modulus of some of the other first regions AR1.

Each of the plurality of second regions AR2 is a region allowing less air to pass therethrough than any of the plurality of first regions AR1. The amount of air passing through each of the plurality of second regions AR2 is preferably 1/10 or less of the amount of air passing through the first region AR1 that allows the largest amount of air to pass therethrough among the plurality of first regions AR1. That is, each of the plurality of second regions AR2 is a semi-closed region having almost no air permeability. Each of the plurality of second regions AR2 may include one or two or more pores 12.

Each of the plurality of second regions AR2 has elasticity. The plurality of second regions AR2 may have the same elastic modulus. The plurality of second regions AR2 may have elastic moduli different from each other. In addition, the elastic modulus of some of the plurality of second regions AR2 may be different from the elastic modulus of some of the other second regions AR2. Furthermore, the elastic modulus of at least one of the plurality of second regions AR2 may be lower than the elastic modulus of the plurality of first regions AR1.

The plurality of first regions AR1 and the plurality of second regions AR2 are alternately arranged. The first region AR1 and the second region AR2 adjacent to each other are in contact with each other. In the present embodiment, the plurality of first regions AR1 are formed in annular shapes having different outer diameters and different inner diameters, and the plurality of second regions AR2 are formed in annular shapes having different outer diameters and different inner diameters. The plurality of first regions AR1 and the plurality of second regions AR2 are alternately arranged about a common center. That is, the plurality of first regions AR1 and the plurality of second regions AR2 are arranged concentrically.

The second region AR2 is disposed on the outermost side of the auxiliary sheet 10. The first region AR1 is disposed on the innermost side of the auxiliary sheet 10. There is no space between the first region AR1 and the second region AR2 adjacent to each other. Each of the plurality of first regions AR1 is surrounded by the inner side second region AR2 and the outer side second region AR2, or by the outer side second region AR2. The entire circumference of each of the plurality of first regions AR1 is surrounded. The area (first total area) of the plurality of first regions AR1 may be larger than the area (second total area) of the plurality of second regions AR2.

The auxiliary sheet 10 described above may be modified as follows.

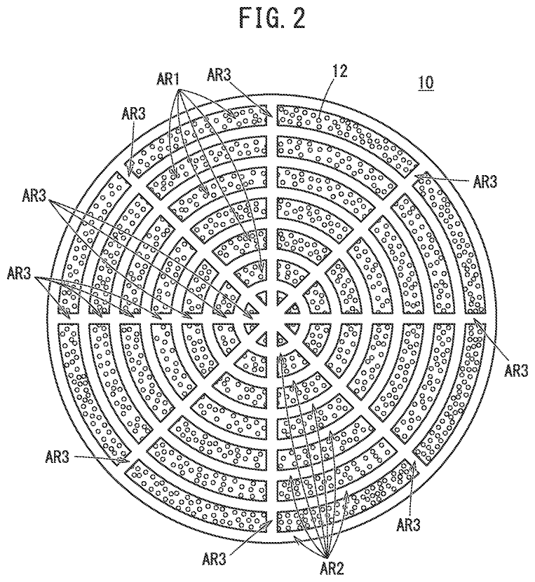

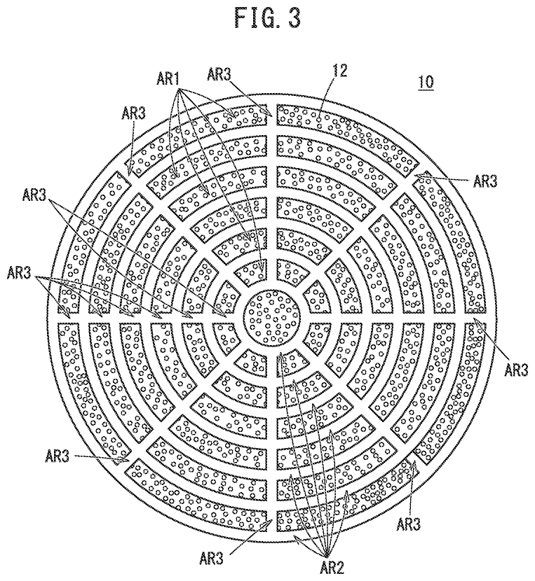

FIG. 2 is a front view showing an auxiliary sheet 10 according to a first modification. FIG. 3 is a front view showing an auxiliary sheet 10 according to a second modification. In FIGS. 2 and 3, the same components as those described in the first embodiment are denoted by the same reference numerals. It should be noted that, concerning the auxiliary sheets 10 of the first modification and the second modification, description overlapping with that of the first embodiment will be omitted.

The auxiliary sheet 10 of each of the first modification and the second modification includes a plurality of third regions AR3 in addition to the plurality of first regions AR1 and the plurality of second regions AR2.

Similarly to the second region AR2, each of the plurality of third regions AR3 is a region allowing less air to pass therethrough than any of the plurality of first regions AR1. The amount of air passing through each of the plurality of third regions AR3 is preferably 1/10 or less of the amount of air passing through the first region AR1 that allows the largest amount of air to pass therethrough among the plurality of first regions AR1. That is, similarly to the second region AR2, each of the plurality of third regions AR3 is a semi-closed region having almost no air permeability. Each of the plurality of third regions AR3 may include one or two or more pores 12.

Each of the plurality of third regions AR3 has elasticity. The plurality of third regions AR3 may have the same elastic modulus. The plurality of third regions AR3 may have elastic moduli different from each other. In addition, the elastic modulus of some of the plurality of third regions AR3 may be different from the elastic modulus of some of the other third regions AR3. Furthermore, the elastic modulus of at least one of the plurality of third regions AR3 may be lower than the elastic modulus of the plurality of first regions AR1.

Each of the plurality of third regions AR3 extends radially along the radial direction of the auxiliary sheet 10. Each of the plurality of third regions AR3 divides the plurality of first regions AR1. In FIG. 2, eight third regions AR3 each dividing one first region AR1 into eight sections are disposed in all of seven first regions AR1. As a result, a total of 56 third regions AR3 are provided in the auxiliary sheet 10. In FIG. 3, eight third regions AR3 each dividing one first region AR1 into eight sections are arranged in six first regions AR1 excluding the innermost first region AR1 among the seven first regions AR1. As a result, a total of 48 third regions AR3 are provided in the auxiliary sheet 10.

The number of divisions into which one first region AR1 is divided is eight in the illustration of FIGS. 2 and 3. However, the number of divisions into which one first region AR1 is divided may be other than eight. That is, the number of divisions into which one first region AR1 is divided is not particularly limited.

Further, as illustrated in FIG. 2, all of the plurality of first regions AR1 may be set as the first regions AR1 to be divided. Furthermore, as illustrated in FIG. 3, some of the plurality of first regions AR1 may be set as the first regions AR1 to be divided. When the number of first regions AR1 to be divided is two or more, the numbers of divisions into which the two or more first regions AR1 are respectively divided may be the same or different from each other.

Further, all or some of the plurality of third regions AR3 may be disposed on lines equally dividing the auxiliary sheet 10 in the circumferential direction. All or some of the plurality of third regions AR3 may be disposed regardless of lines equally dividing the auxiliary sheet 10 in the circumferential direction. It should be noted that FIGS. 2 and 3 illustrate a case where all of the plurality of third regions AR3 are disposed on lines equally dividing the auxiliary sheet 10 into eight sections.

### Second Embodiment

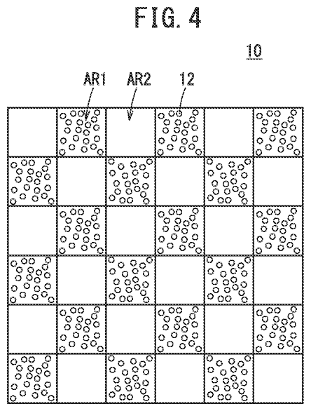

FIG. 4 is a front view showing an auxiliary sheet 10 according to a second embodiment. In FIGS. 4, the same components as those described in the first embodiment are denoted by the same reference numerals. It should be noted that, concerning the auxiliary sheet 10 of the second embodiment, description overlapping with that of the first embodiment will be omitted.

The auxiliary sheet 10 of the present embodiment is formed in a rectangular shape. Each of the plurality of first regions AR1 and the plurality of second regions AR2 included in the auxiliary sheet 10 is formed in a rectangular shape. The plurality of first regions AR1 and the plurality of second regions AR2 are alternately arranged along the row direction and the column direction. The first region AR1 and the second region AR2 adjacent to each other are in contact with each other. In other words, the plurality of first regions AR1 and the plurality of second regions AR2 of the present embodiment are arranged in a matrix.

Each of the plurality of first regions AR1 is surrounded by two, three, or four second regions AR2. Specifically, the first region AR1 corresponding to a corner of the auxiliary sheet 10 is surrounded by two second regions AR2. There is no space between the first region AR1 surrounded by the two second regions AR2, and the two second regions AR2. Within the circumference of the first region AR1 corresponding to the corner of the auxiliary sheet 10, the circumference other than the circumference adjacent to the outside is surrounded by the two second regions AR2. Further, among the outermost first regions AR1, the first regions AR1 except for the first regions AR1 corresponding to the corners of the auxiliary sheet 10 are each surrounded by three second regions AR2. There is no space between the first region AR1 surrounded by the three second regions AR2, and the three second regions AR2. Within the circumference of the first region AR1, the circumference other than the circumference adjacent to the outside is surrounded by the three second regions AR2. In addition, the first regions AR1 other than the outermost first regions AR1 are each surrounded by four second regions AR2. There is no space between the first region AR1 surrounded by the four second regions AR2, and the four second regions AR2. The entire circumference of the first region AR1 is surrounded by the four second regions AR2.

In the case of the present embodiment, the auxiliary sheet 10 may be formed in a shape other than a rectangular shape, such as a circular shape. However, as a prerequisite therefor, the plurality of first regions AR1 and the plurality of second regions AR2 are arranged in a matrix. When the auxiliary sheet 10 is formed in a shape other than a rectangular shape, the first regions AR1 and the second regions AR2 disposed on the outermost sides may be formed in a non-rectangular shape.

### Third Embodiment

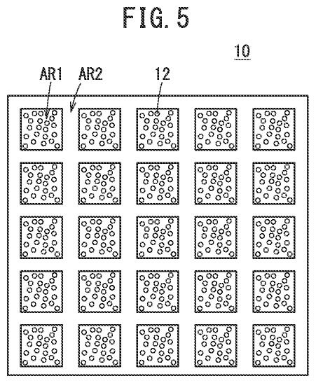

FIG. 5 is a front view showing an auxiliary sheet 10 according to a third embodiment. In FIGS. 5, the same components as those described in the first embodiment are denoted by the same reference numerals. It should be noted that, concerning the auxiliary sheet 10 of the third embodiment, description overlapping with that of the first embodiment will be omitted.

The auxiliary sheet 10 of the present embodiment includes a plurality of first regions AR1 and one second region AR2. According to the present embodiment, the auxiliary sheet 10 and each of the plurality of first regions AR1 included in the auxiliary sheet 10 are formed in a rectangular shape. The plurality of first regions AR1 are arranged in a matrix along the row direction and the column direction. One second region AR2 is formed in a lattice shape so as to individually surround the plurality of first regions AR1.

In the case of the present embodiment, the auxiliary sheet 10 may be formed in a shape other than a rectangular shape, such as a circular shape. However, as a prerequisite therefor, the plurality of first regions AR1 are arranged in a matrix, and one second region AR2 is formed in a lattice shape so as to surround the plurality of first regions AR1.

In addition, in the case of the present embodiment, all or some of the plurality of first regions AR1 may be formed in a shape other than a rectangular shape. However, as a prerequisite therefor, the plurality of first regions AR1 are arranged in a matrix, and one second region AR2 is formed in a lattice shape so as to surround the plurality of first regions AR1.

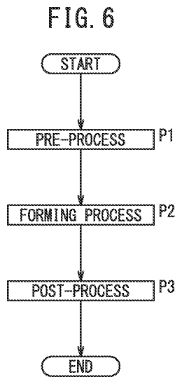

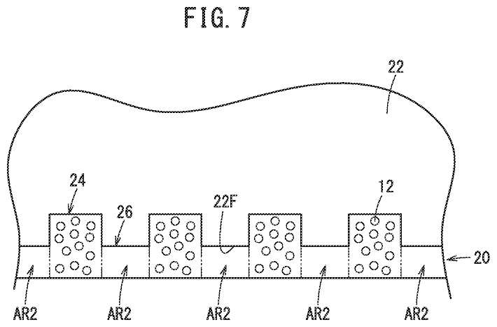

Next, a method for manufacturing the auxiliary sheet 10 will be described. FIG. 6 is a flow chart showing the manufacturing process of the auxiliary sheet 10, and FIG. 7 is a diagram showing a state in which the second regions AR2 are formed. The method for manufacturing the auxiliary sheet 10 includes a pre-process P1, a forming process P2, and a post-process P3.

The pre-process P1 is a process of preparing an elastic sheet (hereinafter referred to as a porous elastic sheet) including a plurality of pores 12 arranged continuously so as to allow air to pass therethrough. The porous elastic sheet prepared in the pre-process P1 may be formed by a predetermined forming method. The porous elastic sheet prepared in the pre-process P1 may be an already formed product. Examples of the porous elastic sheet include a rubber sheet including the plurality of pores 12 arranged continuously so as to allow air to pass therethrough, a foamed polyurethane sheet, and the like.

The forming process P2 is a process of creating the second regions AR2 in the porous elastic sheet. In the forming process P2, as shown in FIG. 7, a press die 22 is pressed against a porous elastic sheet 20 to crush some of the plurality of pores 12 of the porous elastic sheet 20. As a result, the second regions AR2 are formed. Regions other than the second regions AR2 serve as the first regions AR1.

A pressing surface 22F of the press die 22 is provided with an uneven shape corresponding to the auxiliary sheet 10 of the first embodiment (FIG. 1), the auxiliary sheet 10 of the modification (FIG. 2 or FIG. 3), the auxiliary sheet 10 of the second embodiment (FIG. 4), or the auxiliary sheet 10 of the third embodiment (FIG. 5). In FIG. 7, an uneven shape corresponding to the auxiliary sheet 10 of the first embodiment is illustrated.

That is, in the case of the auxiliary sheet 10 of the first embodiment (FIG. 1), a plurality of concave portions 24 and a plurality of convex portions 26 are provided on the pressing surface 22F. The plurality of concave portions 24 form the plurality of first regions AR1. The plurality of convex portions 26 form the plurality of second regions AR2. By pressing the press die 22 against the porous elastic sheet 20, the plurality of second regions AR2 are formed in the porous elastic sheet 20. In the porous elastic sheet 20, the plurality of first regions AR1 and the plurality of second regions AR2 are alternately arranged in a state of being adjacent to each other. In the porous elastic sheet 20, the plurality of first regions AR1 and the plurality of second regions AR2 are arranged concentrically.

In the case of the auxiliary sheet 10 of the modification (FIG. 2 or 3), a plurality of convex portions (not shown) are provided on the pressing surface 22F, in addition to the plurality of concave portions 24 and the plurality of convex portions 26. The plurality of convex portions (not shown) form the plurality of third regions AR3. When the press die 22 is pressed against the porous elastic sheet 20, the plurality of second regions AR2 are formed in the porous elastic sheet 20 as in the first embodiment. In this case, the plurality of third regions AR3 dividing the first regions AR1 are further formed in the porous elastic sheet 20.

In the case of the auxiliary sheet 10 of the second embodiment (FIG. 4), the plurality of concave portions 24 and the plurality of convex portions 26 are provided on the pressing surface 22F. When the press die 22 is pressed against the porous elastic sheet 20, the plurality of second regions AR2 are formed. As a result, in the porous elastic sheet 20, the plurality of first regions AR1 and the plurality of second regions AR2 are alternately arranged in a matrix in a state of being adjacent to each other.

In the case of the auxiliary sheet 10 of the third embodiment (FIG. 5), the plurality of concave portions 24 and one convex portion 26 are provided on the pressing surface 22F. When the press die 22 having this pressing surface 22F is pressed against the porous elastic sheet 20, the plurality of first regions AR1 are arranged in a matrix. In this case, one second region AR2 is further formed in the porous elastic sheet 20 so as to surround the plurality of first regions AR1.

In the forming process P2, the press die 22 that has been heated may be pressed against the porous elastic sheet 20. When the heated press die 22 is pressed, the pores 12 are more easily crushed than in a case where the unheated press die 22 is pressed. As a result, it is possible to increase the reliability of forming a part of the porous elastic sheet 20 having air permeability, as the second region AR2 (semi-closed region) having almost no air permeability.

Further, in the forming process P2, the second region AR2 may be formed using an adhesive, instead of pressing the press die 22 against the porous elastic sheet 20. In the forming process P2, in the case of using an adhesive, the second region AR2 is formed by applying a hot-melt adhesive and hardening the applied hot-melt adhesive into an adhesive having elasticity. Also in this case, as in the case where the press die 22 is pressed against the porous elastic sheet 20, a part of the porous elastic sheet 20 can be formed as the semi-closed region (second region AR2) having almost no air permeability.

The post-process P3 is a process of performing processing after the forming process P2. One porous elastic sheet 20 obtained after the forming process P2 is subjected, as necessary, to a surface treatment for enhancing corrosion resistance or the like, a cleaning treatment for removing dust generated in the forming process P2, or the like. Thereafter, one porous elastic sheet 20 is cut out to manufacture one or a plurality of auxiliary sheets 10 according to the first embodiment, the modifications, the second embodiment, the third embodiment, or the like.

When one auxiliary sheet 10 is manufactured from one porous elastic sheet 20, the post-process P3 may be omitted. When the post-process P3 is not performed, the auxiliary sheet 10 according to the first embodiment, the modifications, the second embodiment, the third embodiment, or the like is manufactured by creating the second region AR2 in the porous elastic sheet 20 in the forming process P2.

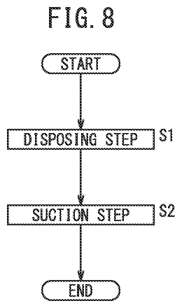

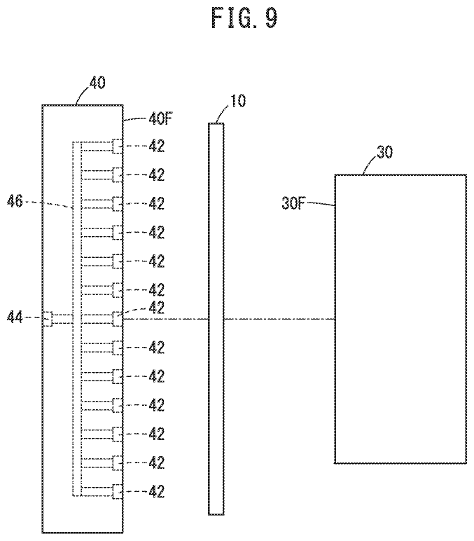

Next, a suction method for sucking a suction object 30 using the auxiliary sheet 10 will be described. FIG. 8 is a flowchart showing a suction process. FIG. 9 is a diagram showing a state in which the auxiliary sheet 10 is disposed. The suction method includes a disposing step S1 and a suction step S2.

The disposing step S1 is a step of disposing the auxiliary sheet 10 between a sucked surface 30F of the suction object 30 and a sucking surface 40F of a table 40. The auxiliary sheet 10 may be the auxiliary sheet 10 of the first embodiment (FIG. 1). The auxiliary sheet 10 may be the auxiliary sheet 10 of the modification (FIG. 2 or 3). The auxiliary sheet 10 may be the auxiliary sheet 10 of the second embodiment (FIG. 4). The auxiliary sheet 10 may be the auxiliary sheet 10 of the third embodiment (FIG. 5).

The auxiliary sheet 10 is disposed between the sucked surface 30F of the suction object 30 and the sucking surface 40F of the table 40. For example, a tool for placing the auxiliary sheet 10 between the sucked surface 30F of the suction object 30 and the sucking surface 40F of the table 40 is used. When the auxiliary sheet 10 is disposed between the sucked surface 30F and the sucking surface 40F, at least one of the sucked surface 30F or the sucking surface 40F may be in contact with or may not be in contact with the auxiliary sheet 10. FIG. 9 illustrates a case where both the sucked surface 30F of the suction object 30 and the sucking surface 40F of the table 40 are not in contact with the auxiliary sheet 10. The area of the sheet surface of the auxiliary sheet 10 may be the same as that of the sucking surface 40F. The area of the sheet surface of the auxiliary sheet 10 may be larger than that of the sucking surface 40F. The area of the sheet surface of the auxiliary sheet 10 may be smaller than that of the sucking surface 40F. In addition, the table 40 may be disposed in a state where the sucking surface 40F extends in the vertical direction. The table 40 may be disposed in a state where the sucking surface 40F extends in the horizontal direction. The table 40 may be disposed in a state where the sucking surface 40F is inclined with respect to the vertical direction or the horizontal direction. FIG. 9 illustrates a case where the area of the sheet surface of the auxiliary sheet 10 is smaller than that of the sucking surface 40F, and the table 40 is disposed in a state where the sucking surface 40F extends in the vertical direction. The table 40 disposed in a state where the sucking surface 40F extends in the vertical direction is used in, for example, a lathe machine or the like.

The suction step S2 is a step of causing the suction object 30 to be sucked onto the sucking surface 40F of the table 40 via the auxiliary sheet 10. The table 40 includes suction openings 42, a joint portion 44, and a flow path 46 (see FIG. 9). The suction openings 42 are provided in the sucking surface 40F. The joint portion 44 is provided on the surface on an opposite to the sucking surface 40F. The flow path 46 allows communication between the suction openings 42 and the joint portion 44. The shape and the number of the suction openings 42 are not particularly limited as long as a workpiece can be sucked onto the sucking surface. A vacuum pump is connected to the joint portion 44. The vacuum pump sucks air outside the table 40 from the suction openings 42 through the flow path 46. As a result, the suction object 30 is sucked onto the sucking surface 40F of the table 40 via the auxiliary sheet 10.

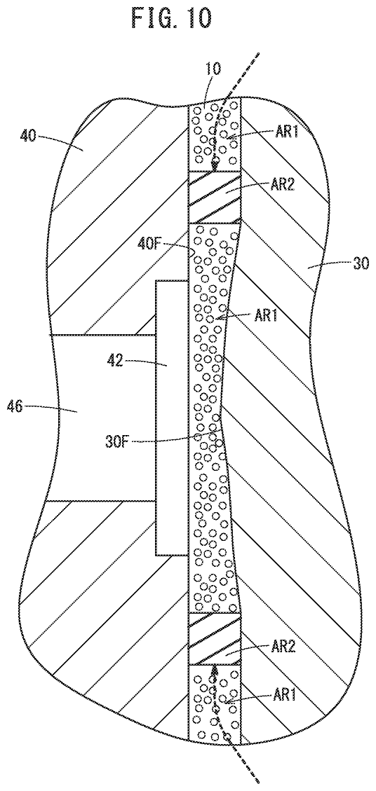

FIG. 10 is a diagram showing a state at the time of suction in which the suction object 30 is sucked onto the table 40 via the auxiliary sheet 10. The plurality of first regions AR1 and the plurality of second regions AR2 (see FIGS. 1 to 4) or one second region AR2 (see FIG. 5) constituting the auxiliary sheet 10 have elasticity. Therefore, even if the sucked surface 30F of the suction object 30 is uneven, the adhesion between the sucked surface 30F and the auxiliary sheet 10 at the time of suction can be enhanced. Although the sucking surface 40F of the table 40 is flat in FIG. 10, the adhesion between the sucking surface 40F and the auxiliary sheet 10 at the time of suction can be enhanced even if the sucking surface 40F is uneven.

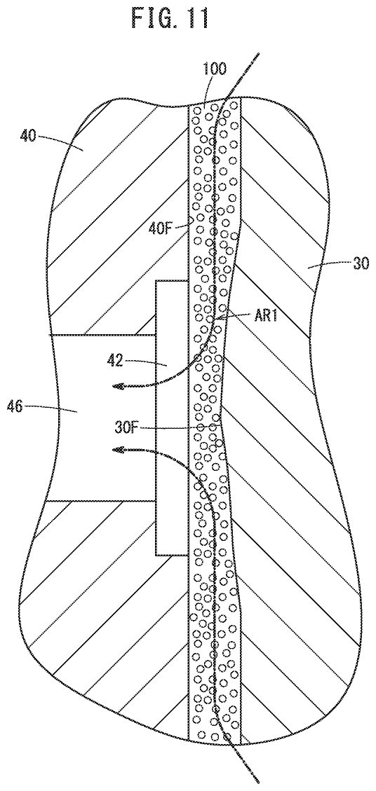

FIG. 11 is a diagram showing a state at the time of suction in which the suction object 30 is sucked onto the table 40 via a conventional porous sheet 100. In FIG. 11, the flow of outside air is indicated by alternate long and short dash lines. The porous sheet 100 does not include the second region AR2. The entire porous sheet 100 is formed only from the first region AR1. When at least one of the sucked surface 30F or the sucking surface 40F is uneven, the force pressing the auxiliary sheet 10 against the sucking surface 40F may be weakened during suction. In this case, in the porous sheet 100, the outside air flows into the inside of the porous sheet 100 via the side of the porous sheet 100, and the outside air having flowed thereinto continues to flow from the suction openings 42 to the flow path 46, whereby the suction force decreases. As a result, the suction of the suction object 30 becomes unstable.

On the other hand, in the above-described auxiliary sheet 10, the plurality of first regions AR1 having air permeability and one or the plurality of second regions AR2 having almost no air permeability are alternately arranged in a state of being adjacent to each other (see FIGS. 1 to 5). Therefore, as indicated by broken lines in FIG. 10, even if outside air flows into the inside of the auxiliary sheet 10 via the side of the auxiliary sheet 10, the second region AR2 acts to block the outside air. Therefore, according to the auxiliary sheet 10, a decrease in the suction force can suppressed and the suction of the suction object 30 can be stabilized.

In a machine tool such as a lathe machine, the suction object 30 may be machined using a tool, and a working fluid may be supplied to the suction object 30 during machining. Therefore, when the suction object 30 is sucked onto the table 40 of the machine tool via the auxiliary sheet 10, the second region AR2 acts to block sludge or the working fluid flowing into the inside of the auxiliary sheet 10 via the side of the auxiliary sheet 10. Accordingly, when the auxiliary sheet 10 is used at the time of sucking the suction object 30 in the machine tool, it is possible to prevent the vacuum pump from sucking the sludge or the working fluid.

Based on the above description, the present invention can be specified as follows.

### (First Invention)

The first aspect of the present invention is the auxiliary sheet (10) that is disposed between the suction object (30) and the sucking surface (40F) onto which the suction object (30) is sucked, the auxiliary sheet (10) being configured to assist suction of the suction object (30). The auxiliary sheet (10) includes: the plurality of first regions (AR1) having elasticity and each including the plurality of pores (12) provided continuously to allow air to pass therethrough; and one or the plurality of second regions (AR2) having elasticity and allowing less air to pass therethrough than the plurality of first regions (AR1). The plurality of first regions (AR1) and the one or plurality of second regions (AR2) are alternately arranged, and the first region (AR1) and the second region (AR2) adjacent to each other are in contact with each other.

This makes it possible to stabilize the suction of the suction object (30). That is, both the first region (AR1) and the second region (AR2) of the auxiliary sheet (10) have elasticity. As a result, at the time of suction in which the suction object (30) is sucked onto the sucking surface (40F) via the auxiliary sheet (10), adhesion between the sucked surface (30F) of the suction object (30) and the auxiliary sheet (10) can be enhanced even if the sucked surface (30F) is uneven, and adhesion between the sucking surface (40F) and the auxiliary sheet (10) can be enhanced even if the sucking surface (40F) is uneven. Further, the first region (AR1) having air permeability and the second region (AR2) having air permeability lower than that of the first region (AR1) are alternately arranged adjacent to each other. As a result, even if pressing of the auxiliary sheet (10) against the sucking surface (40F) is limited during suction due to at least one of the sucked surface (30F) or the sucking surface (40F) being uneven, the second region (AR2) acts to block inflow of outside air from the side of the auxiliary sheet (10), thereby suppressing a decrease in the suction force. In this manner, the suction of the suction object (30) can be stabilized.

Each of the plurality of first regions (AR1) may be surrounded by one or more second regions (AR2). As a result, the action of blocking the inflow of outside air from the side of the auxiliary sheet (10) can be increased, and the suction force can be stabilized. In the case where the entire circumferences of all of the plurality of first regions (AR1) are surrounded, alternatively, among the plurality of first regions (AR1), the entire circumferences of the first regions (AR1) except for the first regions (AR1) disposed on the outermost side of the auxiliary sheet (10) are surrounded, the action of blocking the inflow of outside air from the side of the auxiliary sheet (10) can be greatly increased, and the suction force can be more stabilized.

The area of the plurality of first regions AR1 may be greater than the area of the plurality of second regions AR2. As a result, it is possible to increase the suction force compared to a case where the area of the plurality of first regions (AR1) is smaller than the area of the plurality of second regions (AR2).

The plurality of first regions (AR1) and the plurality of second regions (AR2) may be arranged concentrically. As a result, compared to a case where the plurality of first regions (AR1) and the plurality of second regions (AR2) are arranged in a matrix, one first region (AR1) and one second region (AR2) per unit area can be easily made larger. In addition, when the outermost side of the auxiliary sheet (10) is the second region (AR2), all the circumferences of the plurality of first regions (AR1) can be entirely surrounded.

The auxiliary sheet (10) may include the third region (AR3) having elasticity, allowing less air to pass therethrough than the plurality of first regions (AR1), extending radially along the radial direction, and configured to further divide at least one of the plurality of first regions (AR1). As a result, deformation such as twisting or shrinking of the auxiliary sheet (10) can be suppressed at the time of suction compared to a case where the third region (AR3) is not provided.

The plurality of first regions (AR1) and the plurality of second regions (AR2) may be arranged in a matrix. As a result, it is easier to increase the number of one first region (AR1) and the number of the second regions (AR2) per unit area than in a case where the plurality of first regions (AR1) and the plurality of second regions (AR2) are arranged concentrically.

The plurality of first regions (AR1) may be arranged in a matrix, and one second region (AR2) may be formed in a lattice shape so as to individually surround the plurality of first regions (AR1). This makes it easy to maintain the suction force regardless of the shape of the first regions (AR1).

### (Second Invention)

The second aspect of the present invention is the method for manufacturing the auxiliary sheet (10) that is disposed between the suction object (30) and the sucking surface (40F) configured to suck the suction object (30), the auxiliary sheet (10) being configured to assist suction of the suction object (30). The method for manufacturing the auxiliary sheet (10) includes the pre-process (P1) of preparing the sheet that includes the first region (AR1) having elasticity and including the plurality of pores (12) arranged continuously to allow air to pass therethrough, and a forming process (P2) of forming, in the first region (AR1), one or the plurality of second regions (AR2) having elasticity and allowing less air to pass therethrough than the plurality of first regions (AR1). In the forming process (P2), the one or plurality of second regions (AR2) are formed in a manner so that the plurality of first regions (AR1) and the one or plurality of second regions (AR2) are alternately arranged, and that the first region (AR1) and the second region (AR2) adjacent to each other are in contact with each other.

This makes it possible to stabilize the suction of the suction object (30). That is, both the first region (AR1) and the second region (AR2) of the auxiliary sheet (10) have elasticity. As a result, at the time of suction in which the suction object (30) is sucked onto the sucking surface (40F) via the auxiliary sheet (10), adhesion between the sucked surface (30F) of the suction object (30) and the auxiliary sheet (10) can be enhanced even if the sucked surface (30F) is uneven, and adhesion between the sucking surface (40F) and the auxiliary sheet (10) can be enhanced even if the sucking surface (40F) is uneven. Further, the first region (AR1) having air permeability and the second region (AR2) having air permeability lower than that of the first region (AR1) are alternately arranged adjacent to each other. As a result, even if pressing of the auxiliary sheet (10) against the sucking surface (40F) is limited during suction due to at least one of the sucked surface (30F) or the sucking surface (40F) being uneven, the second region (AR2) can suppress inflow of outside air from the side of the auxiliary sheet (10), thereby suppressing a decrease in the suction force. In this manner, the suction of the suction object (30) can be stabilized.

In the forming process (P2), the one or plurality of second regions (AR2) may be formed by crushing the plurality of pores (12) by pressing of the press die (22). As a result, a part of the sheet can be formed as the semi-closed region (second region (AR2)) having almost no air permeability.

In the forming process (P2), the press die (22) that has been heated may be pressed. As a result, the pores (12) are easily crushed compared to a case where the unheated press die (22) is pressed, and it is possible to increase the reliability of forming a part of the sheet as the semi-closed region (second region (AR2)) having almost no air permeability.

In the forming process (P2), the one or plurality of second regions (AR2) may be formed by applying the hot-melt adhesive and hardening the applied hot-melt adhesive into an adhesive having elasticity. As a result, a part of the sheet can be formed as the semi-closed region (second region (AR2)) having almost no air permeability.

### (Third Invention)

The third aspect of the present invention is the suction method for causing the suction object (30) to be sucked onto the sucking surface (40F) configured to suck the suction object (30), by using the auxiliary sheet (10) that is disposed between the suction object (30) and the sucking surface (40F) and that is configured to assist suction of the suction object (30). The suction method includes a disposing step (S1) of disposing the auxiliary sheet (10) between the sucked surface (30F) of the suction object (30) and the sucking surface (40F) of the table (40), and a suction step (S2) of causing the suction object (30) to be sucked onto the sucking surface (40F) via the auxiliary sheet (10). The auxiliary sheet (10) includes the plurality of first regions (AR1) having elasticity and each including the plurality of pores (12) provided continuously to allow air to pass therethrough, and one or the plurality of second regions (AR2) having elasticity and allowing less air to pass therethrough than the plurality of first regions (AR1), the plurality of first regions (AR1) and the one or plurality of second regions (AR2) are alternately arranged, and the first region (AR1) and the second region (AR2) adjacent to each other are in contact with each other.

This makes it possible to stabilize the suction of the suction object (30). Both the first region (AR1) and the second region (AR2) of the auxiliary sheet (10) have elasticity. As a result, at the time of suction in which the suction object (30) is sucked onto the sucking surface (40F) via the auxiliary sheet (10), adhesion between the sucked surface (30F) of the suction object (30) and the auxiliary sheet (10) can be enhanced even if the sucked surface (30F) is uneven, and adhesion between the sucking surface (40F) and the auxiliary sheet (10) can be enhanced even if the sucking surface (40F) is uneven. Further, the first region (AR1) having air permeability and the second region (AR2) having air permeability lower than that of the first region (AR1) are alternately arranged adjacent to each other. As a result, even if pressing of the auxiliary sheet (10) against the sucking surface (40F) is limited during suction due to at least one of the sucked surface (30F) or the sucking surface (40F) being uneven, the second region (AR2) can suppress inflow of outside air from the side of the auxiliary sheet (10), thereby suppressing a decrease in the suction force. In this manner, the suction of the suction object (30) can be stabilized.

The auxiliary sheet (10) is sucked onto the sucking surface (40F) in a state where the auxiliary sheet (10) is not attached to the suction object (30) or the table (40). This makes it easier to replace the auxiliary sheet (10) than in a case where the auxiliary sheet (10) is attached to the suction object (30) or the table (40). In addition, since the auxiliary sheet (10) does not need to be provided with an attachment region for attachment to the suction object (30) or the table (40), the number of components can be reduced.

1. An auxiliary sheet that is disposed between a suction object and a sucking surface onto which the suction object is sucked, the auxiliary sheet being configured to assist suction of the suction object, the auxiliary sheet comprising:
a plurality of first regions having elasticity and each including a plurality of pores provided continuously to allow air to pass therethrough; and
one or a plurality of second regions having elasticity and allowing less air to pass therethrough than the plurality of first regions,
wherein the plurality of first regions and the one or plurality of second regions are alternately arranged, and the first region and the second region adjacent to each other are in contact with each other.

2. The auxiliary sheet according to claim 1, wherein
each of the plurality of first regions is surrounded by the one or plurality of second regions.

3. The auxiliary sheet according to claim 1, wherein
an area of the plurality of first regions is larger than an area of the plurality of second regions.

4. The auxiliary sheet according to claim 1, wherein
the plurality of first regions and the plurality of second regions are arranged concentrically.

5. The auxiliary sheet according to claim 4, further comprising a third region having elasticity, allowing less air to pass therethrough than the plurality of first regions, extending radially along a radial direction, and configured to further divide at least one of the plurality of first regions.

6. The auxiliary sheet according to claim 1, wherein
the plurality of first regions and the plurality of second regions are arranged in a matrix.

7. The auxiliary sheet according to claim 1, wherein
the plurality of first regions are arranged in a matrix, and
the one second region is formed in a lattice shape so as to individually surround the plurality of first regions.

8. A manufacturing method for manufacturing an auxiliary sheet that is disposed between a suction object and a sucking surface configured to suck the suction object, the auxiliary sheet being configured to assist suction of the suction object, the manufacturing method comprising:
a pre-process of preparing a sheet that includes a first region having elasticity and including a plurality of pores arranged continuously to allow air to pass therethrough; and
a forming process of forming, in the first region, one or a plurality of second regions having elasticity and allowing less air to pass therethrough than a plurality of the first regions, wherein
in the forming process, the one or plurality of second regions are formed in a manner so that the plurality of first regions and the one or plurality of second regions are alternately arranged, and that the first region and the second region adjacent to each other are in contact with each other.

9. The manufacturing method according to claim 8, wherein
in the forming process, the one or plurality of second regions are formed by crushing the plurality of pores by pressing of a press die.

10. The manufacturing method according to claim 9, wherein
in the forming process, the press die that has been heated is pressed.

11. The manufacturing method according to claim 8, wherein
in the forming process, the one or plurality of second regions are formed by applying a hot-melt adhesive and hardening the applied hot-melt adhesive into an adhesive having elasticity.

12. A suction method for causing a suction object to be sucked onto a sucking surface configured to suck the suction object, by using an auxiliary sheet that is disposed between the suction object and the sucking surface and that is configured to assist suction of the suction object, the suction method comprising:
a disposing step of disposing the auxiliary sheet between a sucked surface of the suction object and the sucking surface of a table; and
a suction step of causing the suction object to be sucked onto the sucking surface via the auxiliary sheet,
wherein the auxiliary sheet includes a plurality of first regions having elasticity and each including a plurality of pores provided continuously to allow air to pass therethrough, and one or a plurality of second regions having elasticity and allowing less air to pass therethrough than the plurality of first regions, the plurality of first regions and the one or plurality of second regions are alternately arranged, and the first region and the second region adjacent to each other are in contact with each other.

13. The suction method according to claim 12, wherein
the auxiliary sheet is sucked onto the sucking surface in a state where the auxiliary sheet is not attached to the suction object or the table.
